(19) United States
(12) Patent Application Publication
(10) Pub. No.: US 2026/0342319 A1
(43) Pub. Date: Oct. 29, 2026

(54) Method, Control Circuit and Driving Circuit of Multi-Track Approach for Energy-Recycling Conduction Period Determination

(71) Applicant: xMEMS Labs, Inc., Santa Clara, CA (US)

(72) Inventors: Jing-Meng Liu, San Jose, CA (US); Hung-Chi Huang, Taoyuan City (TW); Ming-Hung Chang, Hsinchu County (TW)

(73) Assignee: xMEMS Labs, Inc., Santa Clara, CA (US)

(21) Appl. No.: 19/654,455

(22) Filed: Apr. 22, 2026

Related U.S. Application Data
(60) Provisional application No. 63/795,370, filed on Apr. 26, 2025.

(51) Int. Cl. H03K 3/012

(52) U.S. Cl. CPC H03K 3/012

(57) ABSTRACT

The present application provides a method of energy-recycling period determination, applied in a control circuit configured to control an energy-recycling circuit performing a plurality of energy-recycling operations. The method includes classifying the plurality of energy-recycling operations into a plurality of tracks; and determining a plurality of energy-recycling periods corresponding to the plurality of tracks.

### CROSS REFERENCE TO RELATED APPLICATIONS

This application claims the benefit of U.S. Provisional Application No. 63/795,370, filed on Apr. 26th, 2025. The content of the application is incorporated herein by reference.

### BACKGROUND OF THE INVENTION

### 1. Field of the Invention

The present application relates to a method, a control circuit and a driving circuit, and more particularly, to a method, a control circuit and a driving circuit exploiting multi-track approach for energy-recycling conduction period determination.

### 2. Description of the Prior Art

Unless otherwise indicated herein, the approaches described in this section are not prior art to the claims in this application and are not admitted as prior art by inclusion in this section.

Energy-recycling circuit, exploiting LC oscillations, has been used within driving circuit for driving capacitive load(s) especially when swapping voltages is desirable (e.g., see US Patent No. 11,057,692, Application No. 18/396,678 and Patent No. 12,107,546), having benefit of reducing power consumption. The energy-recycling circuit basically comprises an inductor and a switching unit coupled between a first capacitive component and a second capacitive component with certain capacitance. During conduction period, the energy-recycling circuit would form a current from one capacitive component to another, so as to recycle electrical energy stored in one capacitive component.

During the conduction period, magnitude of the current would decrease and may eventually return to zero when the conduction period is sufficiently long. If the conduction period is too long, a reverse current will be formed, due to the property of LC oscillation.

Conduction period cannot be too short; otherwise there would be residual charges (electrical energy) which may not be fully recycled. On the other hand, conduction period cannot be too long, otherwise, as mentioned earlier, reverse current will be formed which is not desirable. Hence, determining conduction period for energy-recycling is a critical problem.

In some application scenario, the capacitance thereof is not constant, especially due to significant variation of applied voltages, which causes conduction period determination even more challenging.

Therefore, how to determine conduction period for energy-recycling circuit is a significant objective in the field.

### SUMMARY OF THE INVENTION

It is therefore a primary objective of the present application to provide a method, a control circuit and a driving circuit, to improve over disadvantages of the prior art.

An embodiment of the present invention discloses a method of energy-recycling period determination, applied in a control circuit configured to control an energy-recycling circuit performing a plurality of energy-recycling operations. The method comprises classifying the plurality of energy-recycling operations into a plurality of tracks; and determining a plurality of energy-recycling periods corresponding to the plurality of tracks.

An embodiment of the present invention discloses a control circuit comprising: a classification circuit, configured to classify a plurality of energy-recycling operations into a plurality of tracks; and a determination circuit, configured to determine a plurality of energy-recycling periods corresponding to the plurality of tracks; wherein the control circuit is configured to control an energy-recycling circuit, and the energy-recycling circuit performs the plurality of energy-recycling operations.

An embodiment of the present invention discloses a driving circuit comprising: an energy-recycling circuit, comprising an inductor and a switching unit, coupled between a first node and a second node; a control circuit, configured to control the switching unit such that the energy-recycling circuit performs a plurality of energy-recycling operations; wherein the control circuit classifies the plurality of energy-recycling operations into a plurality of tracks; wherein the control circuit determines a plurality of energy-recycling periods corresponding to the plurality of tracks.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating energy-recycling operations.

FIG. 2 is a schematic diagram illustrating energy-recycling operations.

FIG. 3 is a schematic diagram of an air-pulse generating (APG) device according to an embodiment of the present invention.

FIG. 4 is a schematic diagram of a driving scheme.

FIG. 5 is a schematic diagram of a driving scheme according to an embodiment of the present invention.

FIG. 6 illustrates a curve of capacitance versus applied voltage for an actuating material.

FIG. 7 illustrates a schematic diagram of an APG device possessing asymmetric initial deflection according to an embodiment of the present invention.

FIG. 8 is a schematic diagram of a driving circuit according to an embodiment of the present invention.

FIG. 9 is a schematic diagram of a driving circuit according to an embodiment of the present invention.

FIG. 10 illustrates waveforms of signals within the driving circuit in FIG. 9.

FIG. 11 is a schematic diagram of a driving circuit according to an embodiment of the present invention.

FIG. 12 is a schematic diagram of a process according to an embodiment of the present invention.

### DETAILED DESCRIPTION

The technical features described in the embodiments of the present invention may be mixed or combined in various ways as long as there are no conflicts between them.

In the present invention, the term “coupled to” may refer to direct or indirect connection. “Component A being coupled to component B” may indicate that component A is directly connected to component B, or component A is connected to component B via some component C.

Content of US Patent No. 11,057,692, No. 11,943,585, No. 12,261,567, No. 12,270,836, US Application No. 19/424,094 and No. 19/446,931 is incorporated herein by reference.

Energy-recycling (ER) in the present invention refers to an operation of pouring electrons from one capacitor to another capacitor causing voltages of the two capacitors swapping. Energy-recycling may be applied to a signal generator where the signal generator generates two swapping signals (see No. 11,057,692 and No. 12,261,567).

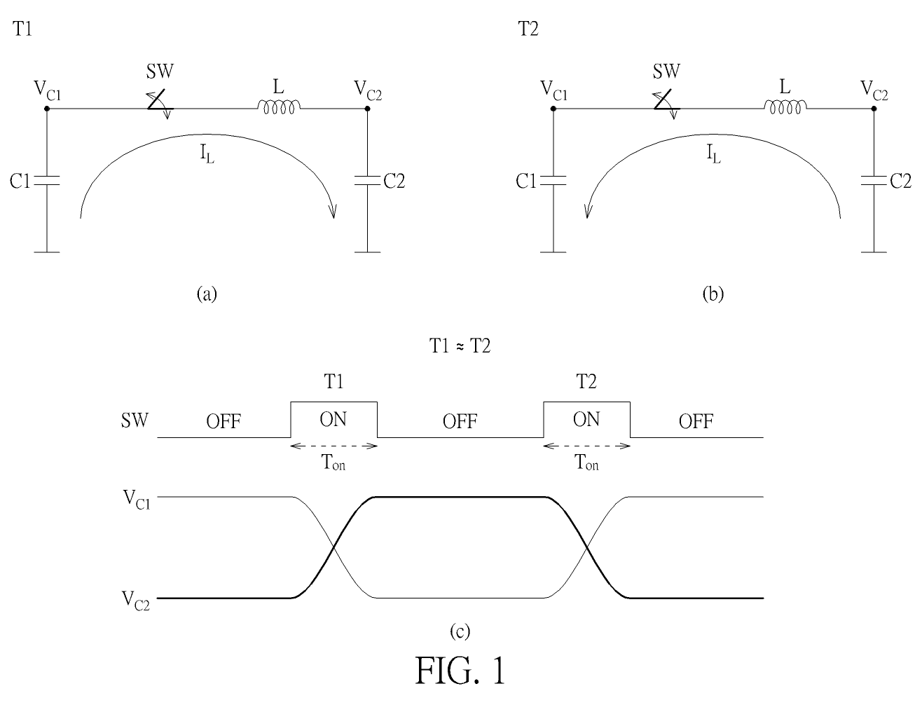

FIG. 1 are schematic diagrams illustrating energy-recycling operations. FIGS. 1(a) and 1(b) illustrates circuit diagrams of ER circuits. FIG. 1(c) illustrates timing diagrams of signal waveforms. The ER circuit comprises an inductor L and a switching unit SW coupled between a first node (annotated as V_{C1}) and a second node (annotated as V_{C2}), where the first node is coupled to a first capacitor C1 and the second node is coupled to a second capacitor C2.

The switching unit SW is configured to control a conducting status (i.e., an ON/OFF status) of the ER circuit or a conducting status between the first node and the second node. In FIGS. 1(a) and 1(b), one switch is used to represent the switching unit SW, which is not limited thereto. In the later embodiment, the switching unit SW may comprise a first switch coupled to a first terminal of the inductor L (e.g., SW1_{ER} shown later) and a second switch coupled to a second terminal of the inductor L (e.g., SW2_{ER} shown later), as taught in US Patent No. 12,261,567.

In FIGS. 1(a) and 1(b), the capacitor C1/C2 or simply C1/C2 is symbolic representation of component with (electric) capacitance. In the present application, the capacitor C1/C2 or simply C1/C2 refers not only to physical discrete capacitor but also to component(s) that exhibits capacitance.

In FIG. 1(c), V_{C1}/ V_{C2} is used to denote a signal or a voltage at the first/second node, and SW is used to denote a control signal for controlling (an ON/OFF status of) the switching unit SW.

In the present application, the control signal of a switch and the switch itself sometimes share the same notation.

Before a time T1, V_{C1} > V_{C2}. Once the switching unit SW is turned ON during the time T1, an inductor current I_{L} flowing from capacitor C1 to capacitor C2 is formed (as shown in FIG. 1(a)), causing V_{C1} to decrease and V_{C2} to increase.

Before a time T2, V_{C1} < V_{C2}. Once the switching unit SW is turned ON during the time T2, an inductor current I_{L} flowing from capacitor C2 to capacitor C1 is formed (as shown in FIG. 1(b)), causing V_{C2} to decrease and V_{C1} to increase.

In other words, during a conduction period or an ER period, denoted as T_{ON}, an LC (LC: Inductor-Capacitor) oscillation is formed and the inductor current I_{L} is formed due to the LC oscillation.

Note that, in order to recycle electric energy stored in the capacitor/capacitance as perfect as possible, the ER period T_{ON} needs to be carefully estimated. Take the time T1 as an example (where the inductor current I_{L} is (mainly) from C1 to C2), if the ER period T_{ON} is too short, there will be residual electrons left in the capacitor C1, which is not fully recycled and causes energy wasted. On the other hand, if the ER period T_{ON} is too long, the LC oscillation would cause a reverse inductor current flowing from C2 to C1, which is not fully recycled and degrades performance of energy efficiency.

US Patent No. 12,270,836 discloses a learning/adjusting/adapting method for finding (sub-)optimal conduction period or ER period T_{ON}. Note that, the mechanism disclosed in No. 12,270,836 works well under an assumption that the ER period is more or less the same all the time (e.g., T1 ≈ T2 as shown in FIG. 1(c)).

However, for some scenario(s), the assumption above may not be valid.

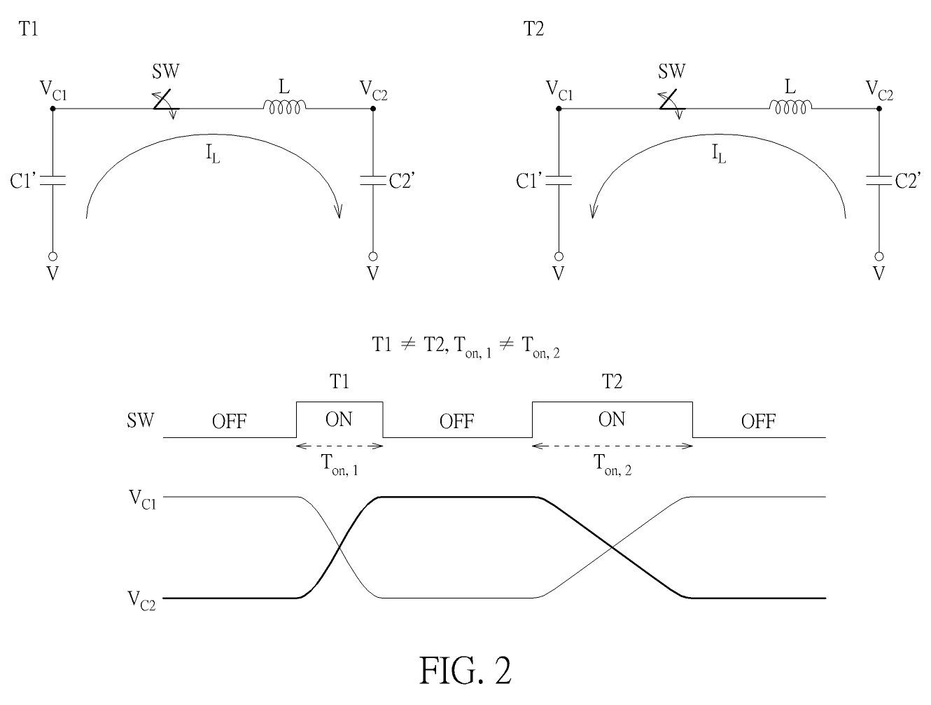

For example, FIG. 2 illustrates an ER operation with different ER period T_{ON}. In FIG. 2, conditions of the time T1 may be different from those of the time T2, causing that the ER period T_{ON,1} corresponding to T1 is different from the ER period T_{ON,2} corresponding to T2.

In this case, simply using the method taught in No. 12,270,836 all the time is insufficient. There is a need to compensate for such deficit.

Before describing the method of the present invention, an application scenario of the signal generator in practical system is first introduced.

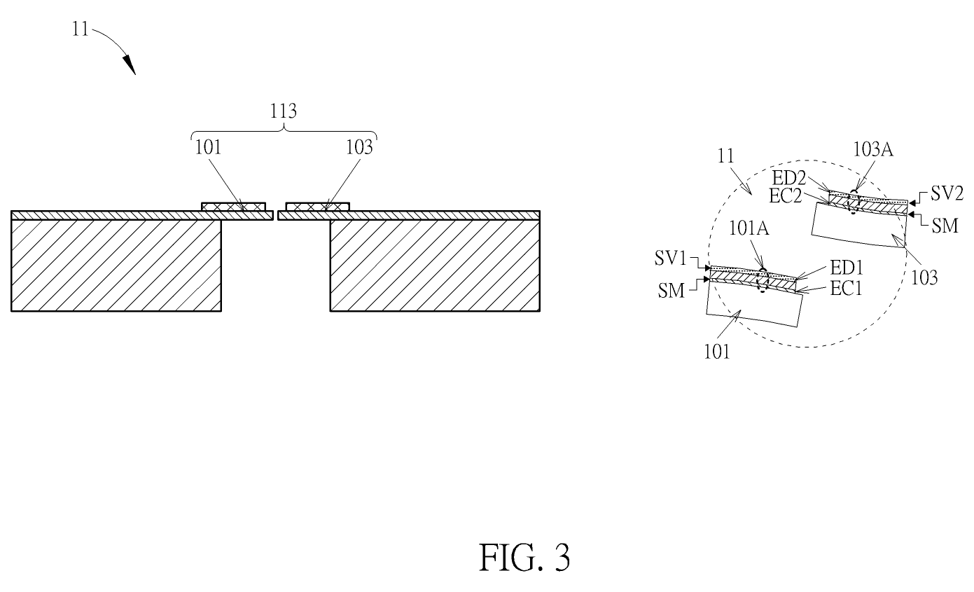

FIG. 3 is a schematic diagram of an air-pulse generating (APG) device 11 according to an embodiment of the present invention. The APG device 11 comprises a flap pair 113. The flap pair 113 comprises a first flap 101 and a second flap 103. In addition, the APG device 11 comprises a first actuator 101A disposed on the first flap 101 and a second actuator 103A disposed on the second flap 103. The first actuator 101A comprises a first differential-mode electrode ED1 and a first common-mode electrode EC1, and the second actuator 103A comprises a second differential-mode electrode ED2 and a second common-mode electrode EC2.

The first/second differential-mode electrode ED1/ED2 receives a first/second differential-mode driving signal SV1/SV2. The first common-mode electrode EC1 and the second common-mode electrode EC2 receive a common-mode driving signal SM.

The flap pair 113 is driven by the first and second differential-mode driving signal SV1 and SV2 to perform a differential-mode movement to form a virtual valve 112. The flap pair 113 is driven by the common-mode driving signal SM to perform a common-mode movement to form a pressure variation. SV1/SV2 may be considered as valve driving signal or demodulation (driving) signal, and SM may be considered as pressure driving signal or modulation (driving) signal.

Operations of the flap pair 113 of the APG device 11, especially regarding the differential-mode movement and the common-mode movement are detailed in Patent No. 11,943,585 and Application No. 19/424,094, which are not narrated herein for brevity.

Driving signal generator for generating differential-mode driving signals SV1 and SV2 or driving signal generator for generating common-mode driving signal SM may perform ER operation and require ER therein. It is crucial to have an accurate estimate of the conduction period for the ER operation.

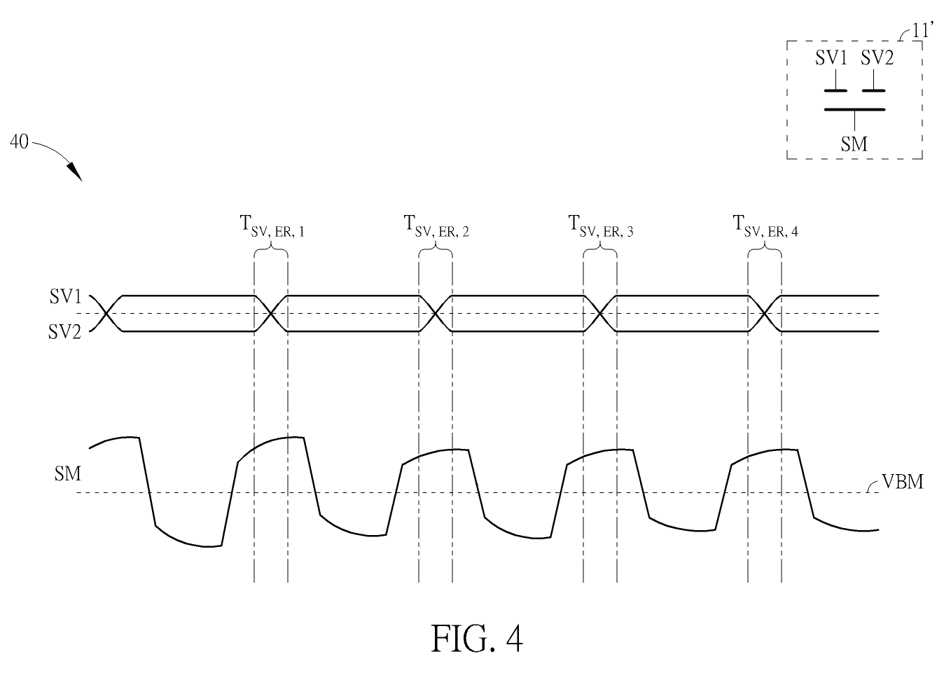

FIG. 4 illustrates a driving scheme 40 of the APG device (e.g., 11/11’), where a differential-mode driving frequency F_{V} (corresponding to SV1/SV2) is a half of a common-mode driving frequency F_{M} (corresponding to SM), i.e., F_{V} = 1/2•F_{M}. As can be seen from FIG. 4, the ER operations for generating the differential-mode driving signals SV1 and SV2 always occur during a period of the common-mode driving signal SM being larger than a threshold VBM, for example. Therefore, the ER periods T_{SV,ER,1}, T_{SV,ER,2}, T_{SV,ER,3}, T_{SV,ER,4}may be more or less the same, and using the method taught in No. 12,270,836 may be sufficient.

However, for the driving scheme with F_{V} = F_{M}, the ER period T_{SV,ER,} k would lose its consistency.

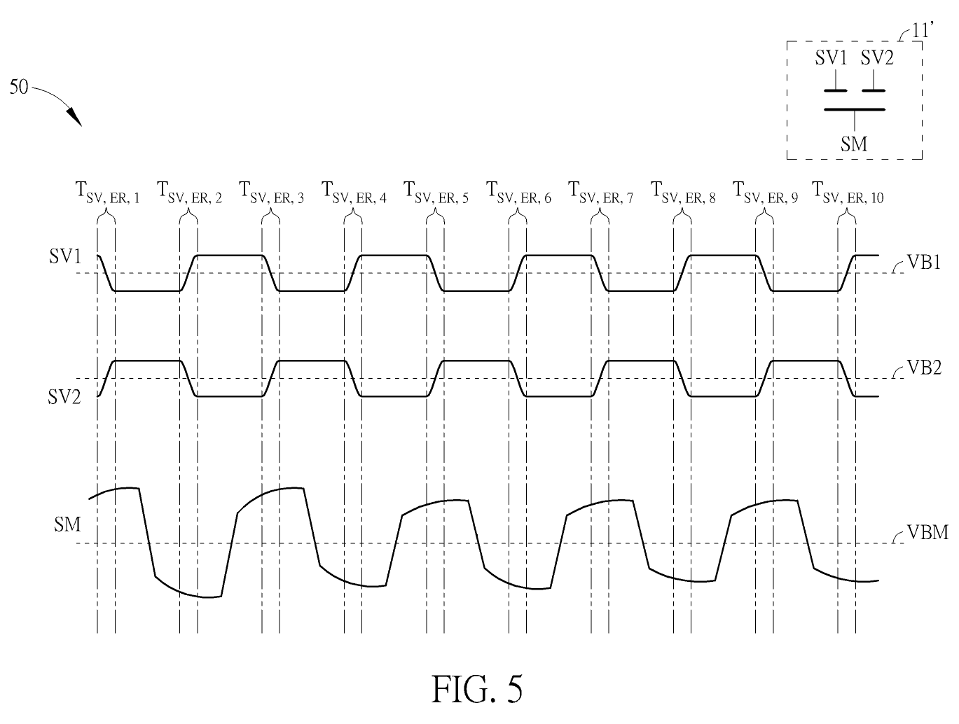

For example, FIG. 5 illustrates a driving scheme 50 of the APG device (e.g., 11/11’). In FIG. 5, the differential-mode driving frequency F_{V} and the common-mode driving frequency F_{M} are the same, i.e., F_{V} = F_{M}, where having F_{V} = F_{M} would bypass the false demodulation issue (detailed in Application No. 19/424,094). Some of the ER operations for generating SV1 and SV2 (e.g., ER periods T_{SV,ER,1}, T_{SV,ER,3}, T_{SV,ER,5}, T_{SV,ER,7}, T_{SV,ER,9} shown in FIG. 5, forming a first set of ER periods/operations) corresponds to a case that the common-mode driving signal SM is larger than the threshold VBM, and another ER operations for generating SV1 and SV2 (e.g., ER periods T_{SV,ER,2}, T_{SV,ER,4}, T_{SV,ER,6}, T_{SV,ER,8}, T_{SV,ER,10} shown in FIG. 5, forming a second set of ER periods/operations) corresponds to another case that the common-mode driving signal SM being less than the threshold VBM.

In FIGS. 4 and 5, the APG device 11’ illustrates an equivalent circuit model representing the physical APG device 11 shown in FIG. 3.

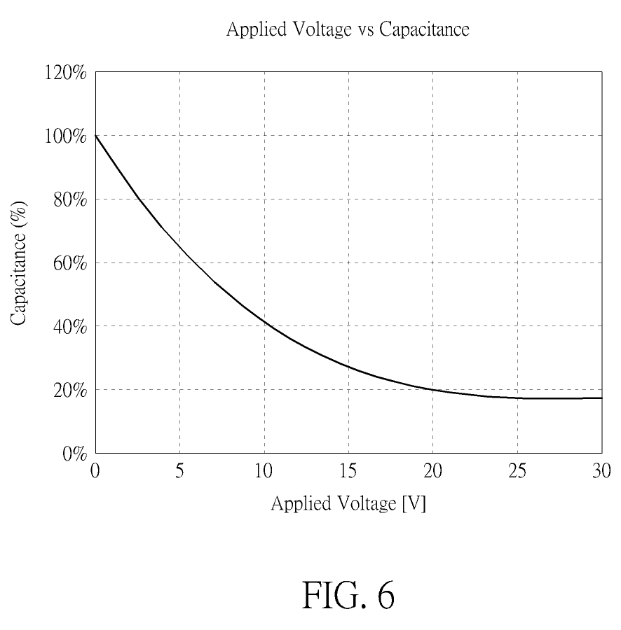

Note that, between the differential-mode electrode (e.g., ED1/ED2) and the common-mode electrode (e.g., EC1/EC2), actuating material (e.g., Lead Zirconate Titanate (PZT)) is disposed in the actuator (101A/103A). Note that, for some actuating material (e.g., PZT but not limited thereto), capacitance has a decreasing relationship with the applied voltage, as shown in FIG. 6.

Suppose C1/C2 represents capacitance between the electrode receiving SV1/SV2 (e.g., ED1/ED2) and the electrode receiving SM (e.g., EC1/EC2). Within the actuator 101A/103A, capacitance C1/C2 corresponding to SM > VBM would be quite different from the one corresponding to SM < VBM. In other words, using the result of T_{SV,ER,2} (where SM < VBM) to adapt subsequent T_{SV,ER,3} (where SM > VBM) is inappropriate.

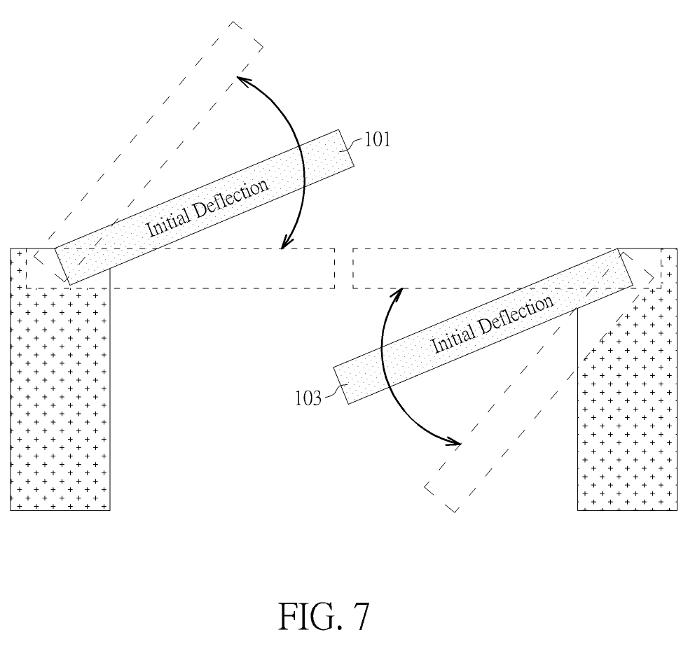

In addition, the driving scheme 50 may be applied to APG devices disclosed in US Application No. 19/424,094 and No. 19/446,931 with F_{V} = F_{M} and asymmetric initial deflection shown in FIG. 7. Details of APG device with asymmetric initial deflection may be referred to No. 19/424,094 and No. 19/446,931.

Again, for some scheme(s) (e.g., the scheme with F_{V} = F_{M}), purely using the method taught in US Patent No. 12,270,836 to obtain ER period may be insufficient.

To remedy this situation, in the present invention, all the ER operations may be classified into multiple tracks (e.g., two tracks in the embodiment shown in FIG. 5), and ER period determination/adaptation/estimation may be performed particularly for each track.

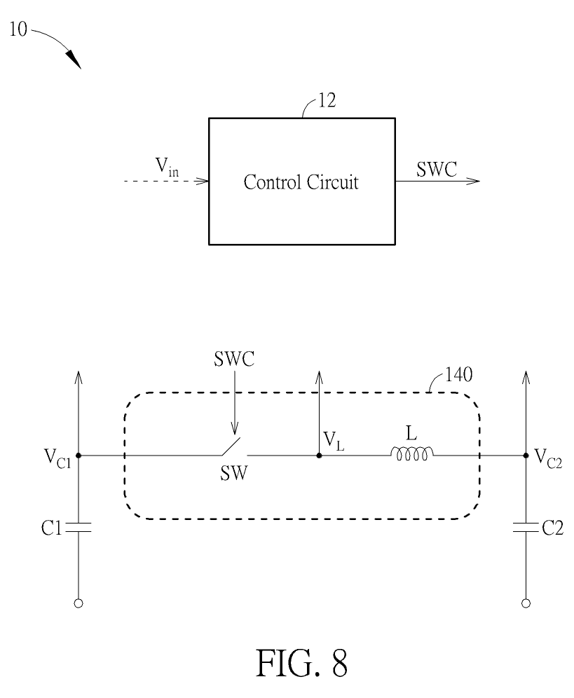

FIG. 8 is a schematic diagram of a driving circuit 10 according to an embodiment of the present invention. The driving circuit 10 comprises a control circuit 12 and an energy-recycling (ER) circuit 140. The ER circuit 140, as mentioned earlier, is coupled between the first node annotated as V_{C1} and the second node annotated as V_{C2}. The ER circuit 140 comprises the inductor L and the switching unit SW. The control circuit 12, which may be realized by digital synthesized control/logic circuit and/or analog circuit, is configured to generate a control signal SWC to control a conduction status of the switching unit SW. Furthermore, the control circuit 12 determines the ER period T_{ON} embedded in the control signal SWC.

Suppose the driving scheme 50is applied, the control circuit 12 may classify all ER periods/operations into two tracks: one ER track (e.g., track A including the ER periods/operations T_{SV,ER,1}, T_{SV,ER,3}, T_{SV,ER,5}, T_{SV,ER,7}, T_{SV,ER,9} corresponding to SM > VBM) and another ER track (e.g., track B including the ER periods/operations T_{SV,ER,2}, T_{SV,ER,4}, T_{SV,ER,6}, T_{SV,ER,8}, T_{SV,ER,10} corresponding to SM < VBM). The control circuit 12 may determine an ER period T_{SV,ER,A} particularly for the ER track A according to the ER periods/operations T_{SV,ER,1}, T_{SV,ER,3}, …, T_{SV,ER,2} k ₊₁ and determine an ER period T_{SV,ER,B} particularly for the ER track B according to the ER periods/operations T_{SV,ER,2}, T_{SV,ER,4}, …, T_{SV,ER,2} k, where k is an integer. After classification, method taught in US Patent No. 12,270,836 may be used to determine T_{SV,ER,A} according to T_{SV,ER,1}, T_{SV,ER,3}, …, T_{SV,ER,2} k ₊₁ and method taught in US Patent No. 12,270,836 may be used to determine T_{SV,ER,B} according to T_{SV,ER,2}, T_{SV,ER,4}, …, T_{SV,ER,2} k.

In an embodiment, the control circuit 12 may optionally capture at least a voltage from V_{C1}, V_{C2}, V_{L} as an input voltage Vᵢₙ for energy-recycling operations classification, e.g., classifying the energy-recycling operations into multiple tracks (e.g., track A and track B) according to the input voltage Vᵢₙ. In other words, the input voltage Vᵢₙ may be (at least) one of V_{C1}, V_{C2} or V_{L}, which is not limited thereto.

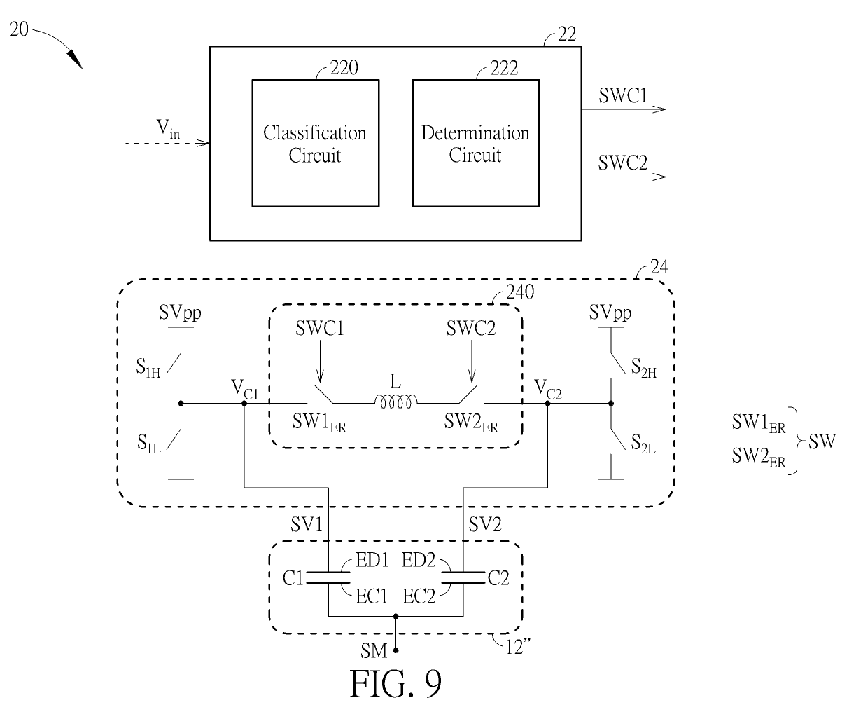

FIG. 9 is a schematic diagram of a driving circuit 20 according to an embodiment of the present invention. The driving circuit 20 comprises a control circuit 22 and a valve driving signal generator 24. The valve driving signal generator 24 comprises the ER circuit 240. The ER circuit 240 comprises switches SW1_{ER} and SW2_{ER}, where the switches SW1_{ER} and SW2_{ER} may be regarded as forming a switching unit SW (which is also shown in FIGS. 1, 2 and 8). The control circuit 22 is configured to generate control signals SWC1 and SWC2 to control the switches SW1_{ER} and SW2_{ER}, respectively.

The control circuit 22 comprises a classification circuit 220 and a determination circuit 222. The classification circuit 220 may be or comprise digital synthesized circuit. The determination circuit 222 may be referred to US Patent No. 12,270,836, which is not narrated herein for brevity.

The classification circuit 220 is configured to classify the energy-recycling operations into multiple tracks (e.g., track A and track B). The determination circuit 222 is configured to determine the energy-recycling periods T_{SV,ER,A} and T_{SV,ER,B} corresponding to track A and track B, respectively.

In an embodiment, the classification circuit 220 may classify the energy-recycling operations according to indices. Note that, the plurality of energy-recycling operations may correspond to a plurality of time indices. For example, index k would be the time index of ER period T_{SV,ER,} k. The (digital synthesized) classification circuit 220 may classify the plurality of energy-recycling operations into track A (corresponding to odd indices) and track B (corresponding to even indices).

In an embodiment, the classification circuit 220 may classify the energy-recycling operations according to a current direction of the inductor current I_{L} flowing through the inductor L. For some energy-recycling operations (or a first set of ER operations), the inductor current I_{L} flows from the first node (annotated as) V_{C1} to the second node (annotated as) V_{C2}. The classification circuit 220 may classify the energy-recycling operations corresponding to a first current direction as a first track (e.g., track A). For another energy-recycling operations (or a second set of ER operations), the inductor current I_{L} flows from the second node (annotated as) V_{C2} to the first node (annotated as) V_{C1}. The classification circuit 220 may classify the energy-recycling operations corresponding to a second current direction as a second track (e.g., track B), where the first current direction and the second current direction are opposite to each other.

Suppose the driving scheme 50 is applied, the classification circuit 220 may classify the energy-recycling operations as track A corresponding to the current direction which is from V_{C1} to V_{C2}, and classify the energy-recycling operations as track B corresponds to the current direction which is from V_{C2} to V_{C1}.

In an embodiment, the classification circuit 220 may classify the plurality of energy-recycling operations into a first track and a second track according to a voltage at an electrode. Specifically, the classification circuit 220 may classify the plurality of energy-recycling operations into the first track corresponding to the voltage being greater than a first threshold and the second track corresponding to the voltage being less than a second threshold, where the first threshold and the second threshold may or may not be the same. In an embodiment, the second threshold may be less than the first threshold.

For example, the classification circuit 220 may classify the plurality of energy-recycling operations according to the voltage V_{C2} at the differential-mode electrode ED2. In an embodiment, the voltages V_{C1} and V_{C2} swing over a range between 0 Volt and a voltage denoted as SVpp. In this embodiment, the classification circuit 220 may classify the energy-recycling operations as the first track (e.g., track A) corresponding to V_{C2} < 1/2•SVpp at a time before upcoming energy-recycling operation and classify the energy-recycling operations as the second track (e.g., track B) corresponding to V_{C2} > 1/2•SVpp at a time before upcoming energy-recycling operation.

In other words, suppose the driving scheme 50 is applied, the classification circuit 220 may classify the energy-recycling operations as track A corresponding to V_{C2} < 1/2•SVpp before the corresponding (e.g., subsequent and consecutive) ER operation, and classify the energy-recycling operations as track B corresponding to V_{C2} > 1/2•SVpp before the corresponding (e.g., subsequent and consecutive) ER operation.

In an embodiment, classification circuit 220 may classify the plurality of energy-recycling operations according to a common-mode voltage (i.e., the voltage of the common-mode driving signal SM during certain ER operation/period, where the common-mode voltage is also denoted as SM) at the common-mode electrode EC1/EC2. The classification circuit 220 may classify the energy-recycling operations as the first track (e.g., track A) corresponding to SM > VBM and classify the energy-recycling operations as the second track (e.g., track B) corresponding to SM < VBM, where the voltage/level VBM can be regarded as a threshold.

Suppose the driving scheme 50 is applied, the classification circuit 220 may classify the energy-recycling operations as track A corresponding to SM > VBM, and classify the energy-recycling operations as track B corresponding to SM < VBM.

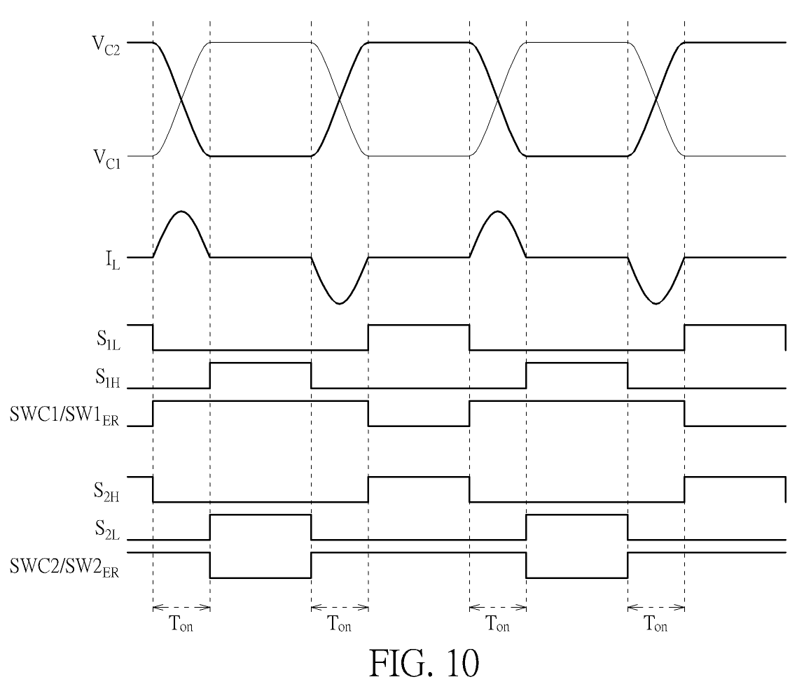

As shown in FIG. 9, the valve driving signal generator 24 within the driving circuit of the present invention comprises switches SW_{1H}, SW₁ _{L}, SW₂ _{H} and SW_{2L}. The switches SW_{1H} and SW₁ _{L} are coupled to the first node annotated by V_{C1}, and the switches SW₂ _{H} and SW_{2L} are coupled to the second node annotated by V_{C2}. The timing diagram of the switches SW_{1H}, SW₁ _{L}, SW₂ _{H} and SW_{2L}, the ER switches SW1_{ER}, SW2_{ER}, the voltages V_{C1}, V_{C2}, and the inductor current I_{L} are illustrated in FIG. 10. The ER conduction period TON is the period when both the ER switches SW1_{ER} and SW2_{ER} are ON/conducted. Operations of the valve driving signal generator 24 are detailed in US Patent No. 12,261,567.

FIG. 9 also illustrates the valve driving signal generator 24 coupled to the APG device 11’’. The APG device 11’’ shows another equivalent circuit model representing the physical APG device 11 as shown in FIG. 3. Difference between the APG device 11’’ (shown in FIG. 9) and the APG device 11’ (shown in FIGS. 4 and 5) is the common-mode electrodes are separated in FIG. 9 but considered as merged in FIGS. 4 and 5.

In order to achieve asymmetric initial deflection shown in FIG. 7 or the driving scheme 50 with VB1 > VB2, a bias circuit or a deflection circuit providing a significant bias voltage to the differential-mode electrode (e.g., ED1) shall be included, which is omitted in FIG. 9.

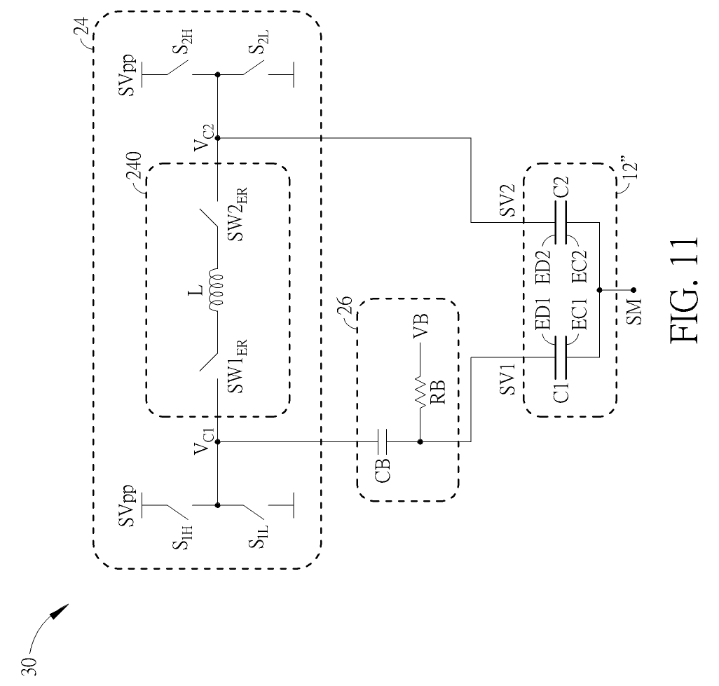

For completeness, a bias/deflection circuit 26 is shown in FIG. 11, where a driving circuit 30 according to an embodiment of the present invention is illustrated. The driving circuit 30 comprises the bias circuit 26, coupled between the first node annotated as V_{C1} and the first differential-mode electrode ED1. The bias circuit 26 comprises a capacitor CB and a resistor RB, where the resistor RB receives a bias voltage VB. The differential-mode electrode ED1 may receive the voltage V_{C1} via the capacitor CB and receives the bias voltage VB via the resistor RB.

Referring to FIGS. 5 and 11, the valve driving signal SV1/SV2 may have an average at a voltage VB1/VB2. When the valve driving signal SV1/SV2 is produced according to the driving circuit 30, VB1/VB2 in FIG. 5 can be expressed as VB1 = VB + 1/2•SVpp and VB2 = 1/2•SVpp.

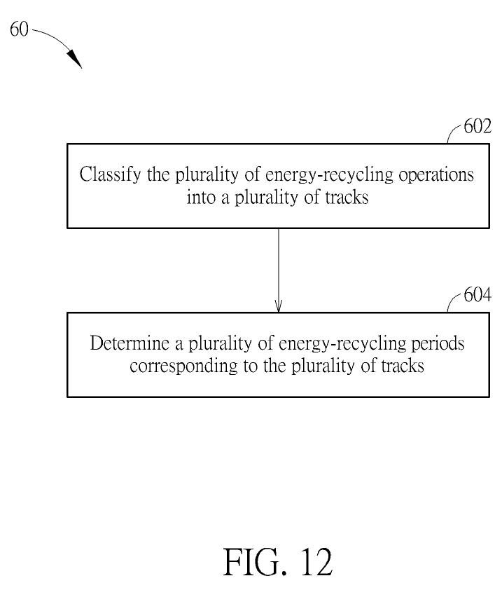

Operations of the control circuit may be summarized as a process 60 shown in FIG. 12, which comprises the following steps:

Step 602: Classify the plurality of energy-recycling operations into a plurality of tracks.

Step 604: Determine a plurality of energy-recycling periods corresponding to the plurality of tracks.

In Step 602, the control circuit 12/22 may classify the plurality of energy-recycling operations into track A and track B. In Step 604, the control circuit 12/22 may determine the energy-recycling periods T_{SV,ER,A} and T_{SV,ER,B} corresponding to track A and track B, respectively.

In short, the present invention adopts a multi-track approach to produce more accurate ER conduction period. Note that, the multi-track approach is not limited to being applied in the differential-mode driving signal generation. The multi-track approach (classifying ER operations into multiple tracks) may be applied to any applications where the environmental condition(s), from perspective of ER circuit, changes with certain pattern(s), which is within the scope of the present invention.

In summary, the present invention categorizes the ER operations into multiple distinct tracks based on criteria such as time indices, inductor current direction, or specific electrode voltage levels (e.g., common-mode voltage), e.g., by the classification circuit. This multi-track approach allows the determination circuit to estimate and adapt precise ER periods (T_{ON}) for each track independently. This mechanism effectively addresses performance degradation caused by capacitance variations and inconsistent ER periods in complex driving schemes, ensuring optimal energy recovery and voltage swapping performance.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A method of energy-recycling period determination, applied in a control circuit configured to control an energy-recycling circuit performing a plurality of energy-recycling operations, the method comprising:
classifying the plurality of energy-recycling operations into a plurality of tracks; and
determining a plurality of energy-recycling periods corresponding to the plurality of tracks.

2. The method of claim 1, wherein the plurality of energy-recycling operations corresponds to a plurality of indices, and the method comprises:
classifying the plurality of energy-recycling operations into the plurality of tracks according to the plurality of indices.

3. The method of claim 2, comprising:
classifying the plurality of energy-recycling operations into a first track and a second track according to the plurality of indices;
wherein the first track corresponds to even indices and the second track corresponds to odd indices.

4. The method of claim 1, wherein the energy-recycling circuit comprises an inductor, and the method comprises:
classifying the plurality of energy-recycling operations into the plurality of tracks according to a current direction of an inductor current flowing through the inductor.

5. The method of claim 4, comprising:
classifying the plurality of energy-recycling operations into a first track and a second track according to the current direction of the inductor current;
wherein the first track corresponds to a first current direction and the second track corresponds to a second current direction;
wherein the first current direction and the second current direction are opposite.

6. The method of claim 1, comprising:
classifying the plurality of energy-recycling operations into the plurality of tracks according to a voltage at an electrode.

7. The method of claim 6, comprising:
classifying the plurality of energy-recycling operations into a first track and a second track according to the voltage;
wherein the first track corresponds to the voltage being greater than a first threshold and the second track corresponds to the voltage being less than a second threshold.

8. The method of claim 1,
wherein the energy-recycling circuit is coupled to a first differential-mode electrode and a second differential-mode electrode;
wherein a first capacitance is formed between the first differential-mode electrode and a common-mode electrode.

9. The method of claim 8, comprising:
classifying the plurality of energy-recycling operations into the plurality of tracks according to a common-mode voltage at the common-mode electrode.

10. The method of claim 9, comprising:
classifying the plurality of energy-recycling operations into a first track and a second track;
wherein the first track corresponds to the common-mode voltage being greater than a threshold and the second track corresponds to the common-mode voltage being less than the threshold.

11. The method of claim 1,
wherein the energy-recycling circuit is configured to produce driving signals to drive an air-pulse generating (APG) device;
wherein the APG device comprises a flap pair and the flap pair comprises a first flap and a second flap;
wherein the APG device comprises a first actuator and a second actuator disposed on the first flap and the second flap, respectively;
wherein the first actuator comprises a first differential-mode electrode and a first common-mode electrode, and the second actuator comprises a second differential-mode electrode and a second common-mode electrode;
wherein the first common-mode electrode and the second common-mode electrode receive a common-mode voltage.

12. A control circuit, comprising:
a classification circuit, configured to classify a plurality of energy-recycling operations into a plurality of tracks; and
a determination circuit, configured to determine a plurality of energy-recycling periods corresponding to the plurality of tracks;
wherein the control circuit is configured to control an energy-recycling circuit, and the energy-recycling circuit performs the plurality of energy-recycling operations.

13. The control circuit of claim 12,
wherein the plurality of energy-recycling operations corresponds to a plurality of indices;
wherein the classification circuit classifies the plurality of energy-recycling operations into a first track and a second track according to the plurality of indices;
wherein the first track corresponds to even indices, and the second track corresponds to odd indices.

14. The control circuit of claim 12,
wherein the energy-recycling circuit comprises an inductor;
wherein the classification circuit classifies the plurality of energy-recycling operations into a first track and a second track according to a current direction of an inductor current;
wherein the first track corresponds to a first current direction and the second track corresponds to a second current direction;
wherein the first current direction and the second current direction are opposite.

15. The control circuit of claim 12,
wherein the classification circuit classifies the plurality of energy-recycling operations into a first track and a second track according to a voltage at an electrode;
wherein the first track corresponds to the voltage being greater than a first threshold and the second track corresponds to the voltage being less than a second threshold.

16. The control circuit of claim 12,
wherein the energy-recycling circuit is coupled to a first differential-mode electrode and a second differential-mode electrode;
wherein a first capacitance is formed between the first differential-mode electrode and a common-mode electrode.

17. The control circuit of claim 16,
wherein the classification circuit classifies the plurality of energy-recycling operations into a first track and a second track according to a common-mode voltage at the common-mode electrode;
wherein the first track corresponds to the common-mode voltage being greater than a threshold and the second track corresponds to the common-mode voltage being less than the threshold.

18. The control circuit of claim 12,
wherein the energy-recycling circuit is configured to produce driving signals to drive an air-pulse generating (APG) device;
wherein the APG device comprises a flap pair and the flap pair comprises a first flap and a second flap;
wherein the APG device comprises a first actuator and a second actuator disposed on the first flap and the second flap, respectively;
wherein the first actuator comprises a first differential-mode electrode and a first common-mode electrode, and the second actuator comprises a second differential-mode electrode and a second common-mode electrode;
wherein the first common-mode electrode and the second common-mode electrode receive a common-mode voltage.

19. The control circuit of claim 12,
wherein the energy-recycling circuit comprises an inductor and a switching unit;
wherein the switching unit is controlled by the control circuit to be conducted during the plurality of energy-recycling operations.

20. A driving circuit, comprising:
an energy-recycling circuit, comprising an inductor and a switching unit, coupled between a first node and a second node;
a control circuit, configured to control the switching unit such that the energy-recycling circuit performs a plurality of energy-recycling operations;
wherein the control circuit classifies the plurality of energy-recycling operations into a plurality of tracks;
wherein the control circuit determines a plurality of energy-recycling periods corresponding to the plurality of tracks.

21. The driving circuit of claim 20,
wherein the plurality of energy-recycling operations corresponds to a plurality of indices;
wherein the control circuit classifies the plurality of energy-recycling operations into a first track and a second track according to the plurality of indices;
wherein the first track corresponds to even indices, and the second track corresponds to odd indices.

22. The driving circuit of claim 20,
wherein the control circuit classifies the plurality of energy-recycling operations into a first track and a second track according to a current direction of the inductor current flowing through the inductor;
wherein the first track corresponds to a first current direction and the second track corresponds to a second current direction;
wherein the first current direction and the second current direction are opposite.

23. The driving circuit of claim 20, comprising:
a first switch, a second switch, a third switch and a fourth switch;
wherein the energy-recycling circuit is coupled between a first node and a second node;
wherein the first switch and the second switch are coupled to the first node, and the third switch and the fourth switch are coupled to the second node.

24. The driving circuit of claim 23,
wherein the driving circuit is configured to drive an air-pulse generating (APG) device;
wherein the APG device comprises a flap pair and the flap pair comprises a first flap and a second flap;
wherein the APG device comprises a first actuator and a second actuator disposed on the first flap and the second flap, respectively;
wherein the flap pair performs a differential-mode movement;
wherein the first actuator comprises a first differential-mode electrode coupled to the first node, and the second actuator comprises a second differential-mode electrode coupled to the second node.

25. The driving circuit of claim 24,
wherein the flap pair performs a common-mode movement according to a common-mode voltage.

26. The driving circuit of claim 25,
wherein the control circuit classifies the plurality of energy-recycling operations into a first track and a second track according to the common-mode voltage at the common-mode electrode;
wherein the first track corresponds to the common-mode voltage being greater than a threshold and the second track corresponds to the common-mode voltage being less than the threshold.

27. The driving circuit of claim 25,
wherein the differential-mode movement corresponds to a differential-mode frequency and the common-mode movement corresponds to a common-mode frequency;
wherein the differential-mode frequency and the common-mode frequency are the same.

28. The driving circuit of claim 24,
wherein the flap pair possesses an asymmetric initial deflection when performing the differential-mode movement.
